(19) United States
(12) Patent Application Publication
(10) Pub. No.: US 2013/0252373 A1
(43) Pub. Date: Sep. 26, 2013

(54) Method for Depositing a Coating on a Substrate by Chemical Vapour Deposition

(71) Applicants: Sam Siau, Arendonk (BE); Franz Horzenberger, Assenede (BE); Kurt De Sloover, Gistel (BE)

(72) Inventors: Sam Siau, Arendonk (BE); Franz Horzenberger, Assenede (BE); Kurt De Sloover, Gistel (BE)

(73) Assignee: OCAS Onderzoekscentrum Voor Aanwending Van Staal N.V., Zelzate (BE)

(21) Appl. No.: 13/819,246

(22) PCT Filed: Aug. 26, 2011
(86) PCT No.: PCT/EP2011/064759

§ 371 Date: Jun. 11, 2013

(30) Foreign Application Priority Data
Aug. 27, 2010 (EP) 10174302.9
Mar. 4, 2011 (EP) 11157010.7

(51) Int. Cl. C23C 4/12; H01L 31/0216

(52) U.S. Cl. CPC C23C 4/124; H01L 31/02167
USPC 438/73; 427/446; 427/452

(57) ABSTRACT

The present invention is related to a method for depositing a coating on a substrate (2) by a flame-assisted chemical vapour deposition technique, wherein the substrate is exposed to a flame produced by a burner (1), while a flow of precursor elements is added to said flame, and wherein the substrate is subjected to a relative movement with respect to said burner wherein the flame is dragged out along a reaction zone (3) situated behind the burner, and wherein the relative speed of the substrate with respect to the flame is higher than 30 m/min.

### FIELD OF THE INVENTION

The present invention is related to methods for depositing an inorganic coating on a substrate via chemical vapour deposition (CVD), in particular by flame assisted CVD (FACVD) or Combustion CVD (CCVD).

### STATE OF THE ART

FACVD and CCVD are variants of CVD that involve the combustion of liquid or gaseous precursors injected and/or delivered into diffused or premixed flames where the precursor will decompose/vaporize and undergo a chemical reaction/combustion in the flame. CCVD is in fact an FACVD-based method. Both techniques are described in Progress in Materials Science 48 (2003), pp. 140-144.

The possibility of combining atmospheric pressure and low temperature during processing makes FACVD/CCVD a useful technique for various applications in which high throughput coating is required.

However, processing speeds have so far been limited due to a deterioration of coating quality and/or coating thickness at high relative substrate speeds, i.e. speed of the substrate relative to the flame. In particular, at speeds above 30 m/min, current FACVD/CCVD techniques do not allow to obtain coatings with sufficient quality, as assessed by the obtainable coating thickness and by a carbon black test in combination with a colour measurement.

In particular in the case of heat sensitive surfaces, such as painted metal sheets, polymer substrates such as polycarbonate substrates, or other materials such as glass or textiles, it has been found to be difficult to obtain good quality coatings by FACVD due to the material itself being destroyed by the high temperatures, or due to undesired chemical or physical reactions/transformations taking place just underneath the outermost surface of the substrate, causing damage in terms of coating adhesion, durability etc.

DE102004029911A1 discloses a method for successfully depositing Ti-oxide and Si-oxide, by not directly injecting the precursor into the flame, but by providing the precursor flow in the vicinity of two FACVD burners. The process speed of this process is however also limited to 30 m/min.

In US2009/0233000, a conductive material is deposited on a substrate by combusting a premixed fuel and oxidant to form a stagnation flame against a moving substrate which stabilizes the stagnation flame and by introducing at least one precursor to the flame to form a conducting material on the substrate. The document discloses that it is possible to maintain a stagnation flame even when the substrate is moving with respect to the flame. The stagnation flame is not affected by the movement of the substrate. According to “Combustion Physics” by Law, Cambridge, 2006, also cited in US 2009/0233000, a stagnation flame is characterized by a hydrodynamical stretch of the flame. Such a hydrodynamical stretch requires a constantly changing flowing section through which the gas flux propagates. Only in the specific case of a burner facing upward towards a stabilizing surface above it, a stagnation flame, as described in US 2009/0233000 can be achieved. It is believed also that a stable stagnation flame is only obtainable at specific values of the burner gas flows and at high relative speeds between the substrate and the flame, such as the exemplary value of 4 m/s (240 m/min) disclosed in the cited document. This is therefore a technique with a very limited field of application.

### AIMS OF THE INVENTION

The present invention aims to provide an FACVD/CCVD method capable of obtaining good inorganic coating quality, in particular on heat-sensitive materials.

### SUMMARY OF THE INVENTION

The invention is related to a method as disclosed in the appended claims. The invention thus concerns a method for depositing a coating on a substrate by a flame-assisted chemical vapour deposition technique, wherein the substrate is exposed to a flame produced by a burner, while a flow of precursor elements is added to said flame, and wherein the substrate is subjected to a relative movement with respect to said burner, wherein the flame is dragged out along a reaction zone situated behind the burner, wherein the relative speed of the substrate with respect to the flame is higher than 30 m/min. According to further preferred embodiments, the relative substrate speed is higher than 40 m/min and higher than 50 m/min respectively. In the context of the present description, FACVD includes any chemical vapour deposition technique involving the use of a flame. FACVD applied in the present invention thus includes what is known in this technical domain as Combustion CVD (CCVD).

According to a preferred embodiment, the substrate comprises on its surface or consists of a heat sensitive material. In the context of the present invention, a ‘heat-sensitive material’ is defined as a material which cannot be coated by FACVD when the relative substrate speed is 30 m/min or lower and when no external cooling is applied. External cooling is here defined as a forced cooling, i.e. an active effort to cool down the substrate, in addition to the cooling down of the substrate through contact with the ambient air. So when ‘no external cooling’ is applied, this means that the substrate cools down only by contact with the ambient (natural convection).

In the invention, the precursor flow and the substrate pre-heating temperature are such that the precursor reactions for forming the coating substantially take place in said reaction zone located behind the burner, with respect to the direction of the movement of the burner relative to the substrate. Said reactions allow to obtain superior coating quality and thickness without damaging the substrate.

According to the preferred embodiment, a coating thickness of minimum 10 nm and a carbon black/colour change rating of less than 1 is obtained.

According to the preferred embodiment of the invention, no external cooling is done on the substrate during the relative movement of the substrate with respect to the burner. Possibly, the substrate may be cooled intermittently by moving the substrate away from and back into the flame during subsequent intervals of time. This intermittent cooling therefore still falls under the above-described meaning of ‘no external cooling’. External cooling (i.e. forced cooling such as water cooling), whereas no requirement, can be used optionally.

The substrate may comprise on its surface or consist of a polyester based material or an organic material. The substrate may be a metal substrate painted with a polyester based paint layer or with an organic film.

In the latter two cases, when intermittent cooling is applied, the relative substrate speed may be between 40 m/min and 110 m/min. When no external cooling and no intermittent cooling is applied, the relative substrate speed may be between 110 m/min and 140 m/min.

In an embodiment of the invention, the substrate comprises on its surface or consists of glass, wherein no external cooling and no intermittent cooling is applied and wherein the relative substrate speed is higher than 30 m/min and up to 80 m/min.

In an embodiment of the invention, the substrate comprises on its surface or consists of polystyrene, wherein no external cooling and no intermittent cooling is applied and wherein the relative substrate speed is between 60 m/min and 100 m/min.

In an embodiment of the invention, the substrate comprises on its surface or consists of polymethylmethacrylate, wherein no external cooling and no intermittent cooling is applied and wherein the relative substrate speed is between 60 m/min and 110 m/min.

In an embodiment of the invention, the substrate comprises on its surface or consists of polypropylene or textile, wherein no external cooling and no intermittent cooling is applied and wherein the relative substrate speed is between 120 m/min and 140 m/min.

In an embodiment of the invention, the substrate comprises on its surface or consists of polycarbonate, wherein no external cooling and no intermittent cooling is applied and wherein the relative substrate speed is between 60 m/min and 140 m/min.

In an embodiment of the invention, the substrate comprises on its surface or consists of laminate or wood, and wherein no external cooling and no intermittent cooling is applied and wherein the relative substrate speed is between 40 m/min and 100 m/min.

In an embodiment of the invention, the substrate comprises on its surface or consists of polyvinylchloride, and wherein no external cooling and no intermittent cooling is applied and wherein the relative substrate speed is between 90 m/min and 100 m/min. According to a preferred embodiment, the substrate material is not silicone rubber.

Preferably, the ratio of the precursor flow relative to the burner gas flow is between 1.9×10⁻⁶ and 2.8×10⁻⁶ and/or the substrate pre-heating temperature is between 40° C. and 75° C.

According to a preferred embodiment, the coating is a silicon oxide coating. In other words, the precursor elements are configured to produce a silicon oxide coating.

The invention is also related to the use of the method of the invention in the production of solar cells comprising a glass or polycarbonate layer, wherein a layer of silicon oxide is applied onto said glass or polycarbonate layer.

According to an embodiment, the substrate comprises on its surface or consists of a heat sensitive material, wherein the coating deposition takes place in two or more deposition steps on a optionally pre-heated substrate, each deposition step consisting of a number of subsequent passes on the same portion of the substrate, each pass consisting of a movement of the substrate relative to the flame at a speed of 30 m/min or more, no external cooling being applied during said movement, and wherein after each deposition step, the substrate is subjected to a cooling step, wherein the substrate cools down to its initial temperature.

In the latter embodiment, the substrate may be removed from the flame after each step, during a period sufficiently long to let the substrate cool down under ambient air to its initial temperature, or the substrate may be removed from the flame after each step and cooled down to its initial temperature by forced cooling.

Said heat sensitive material may be polypropylene (PP), polyvinylchloride (PVC) or Acrylonitrile Butadiene Styrene (ABS).

According to an embodiment, said heat-sensitive material is PP, and:
the relative speed between the flame and the substrate is between 80 m/min and 200 m/min,
each step comprises two or three passes,
the cooling time between steps is at least 2 minutes,
the substrate is preheated to a temperature between 40° C. and 75° C.

According to another embodiment, said heat-sensitive material is PVC, and:
the relative speed between the flame and the substrate is between 60 m/min and 80 m/min,
each step comprises two or three passes,
the cooling time between steps is at least 10 minutes,
the substrate is not pre-heated.

According to another embodiment, said heat-sensitive material is ABS, and:
the relative speed between the flame and the substrate is between 80 m/min and 200 m/min,
each step comprises two or three passes,
the cooling time between steps is at least 10 minutes,
the substrate is not pre-heated.

In the embodiments of the previous 6 paragraphs, the number of steps may be 3 or 4, and the following may be the case:
the precursor flow is between 200 μl/min and 600 μl/min,
the ratio of the precursor flow relative to the burner gas flow (fuel gas+air) is between 0.9×10⁻⁶ and 2.8×10⁻⁶(liter_{precursor}/liter_{gas}),
the distance burner substrate is between 10 mm and 15 mm.

### BRIEF DESCRIPTION OF THE FIGURES

FIG. 1 shows a schematic view of an FACVD setup according to the invention.

FIG. 2 shows various regions corresponding to various coating qualities in terms of the deposition speed per unit burner power, as a function of the relative substrate speed.

FIG. 3 shows the thickness of coatings deposited on pre-painted steel substrates, as a function of the relative substrate speed, for different external cooling regimes.

FIG. 4 shows the same graph as in FIG. 3, with a curve fitted onto the measurement points.

FIG. 5 illustrates the four zones used in a carbon black test.

### DETAILED DESCRIPTION OF THE INVENTION

The inventors of the present invention have found that in particular on heat-sensitive materials such as described above, good coating quality in terms of thickness and carbon black/colour measurements can be obtained by FACVD, at a relative substrate speed (i.e. speed of the substrate with respect to the flame) above 30 m/min, without requiring external cooling. According to a more preferred embodiment, the relative substrate speed is above 40 m/min. According to a further preferred embodiment, the relative substrate speed is above 50 m/min. According to the invention, the flame characteristics are such that a ‘drag effect’ takes place of the substrate on the flame, as illustrated in FIG. 1. The arrow shows the relative speed of the FACVD head 1 with respect to the substrate 2. At high relative speeds, the flame extends over a reaction zone 3 behind the FACVD head. This type of flame is obtained under the conditions in terms of burner gas speeds and other parameters, different from the parameters that are known to lead to a stagnation flame as defined in US2009/0233000. The deformation of the flame is due to friction forces between the flame and the substrate surface. Contrary to the stagnation flame of US2009/0233000, the flame in the method of the invention is influenced by the relative movement of the substrate. More precisely, the flame is dragged out (i.e. stretched out) in a reaction zone 3 situated behind the burner (‘behind’ as seen in the direction of the burner movement relative to the substrate). It has been found that the drag effect reduces the heat flow towards the substrate, whilst still providing sufficient heat for the precursor elements to react and form a coating. The reduced heat flow avoids the undesired chemical and physical reaction taking place underneath the substrate surface. The FACVD method of the invention can take place at near-atmospheric, atmospheric or higher pressure.

The present invention has established preferred ranges for a number of process parameters which allow for the above described drag effect to take place so that a high quality coating is obtained at relative substrate speeds above 30 m/min. The maximum applicable relative speed may depend on the substrate material. According to a preferred embodiment applicable to a majority of substrate materials, the relative substrate speed is up to 200 m/min. Specific preferred speed ranges applicable to specific substrate materials will be given later in this description. In scientific terms, it is necessary to maintain the dynamic temperature between given limits. The dynamic temperature is defined as the temperature at each instantaneous moment in time during the deposition process for a small material element of the substrate material. The dynamic temperature is a function of the flows of entropy and energy (mainly defined by temperature and precursor reactions) in the thermodynamic system defined by the reaction zone 3. According to preferred embodiments, conditions for obtaining a good coating are also related to the external cooling applied to the substrate. According to preferred embodiments, no external cooling is applied instead of the continuous cooling by a water bath or heat sink, which is applied in prior art methods. Also, preferred ranges have been established for a number of process parameters, in particular the precursor flow relative to the flow of burner gases, and the pre-heating temperature of the substrate.

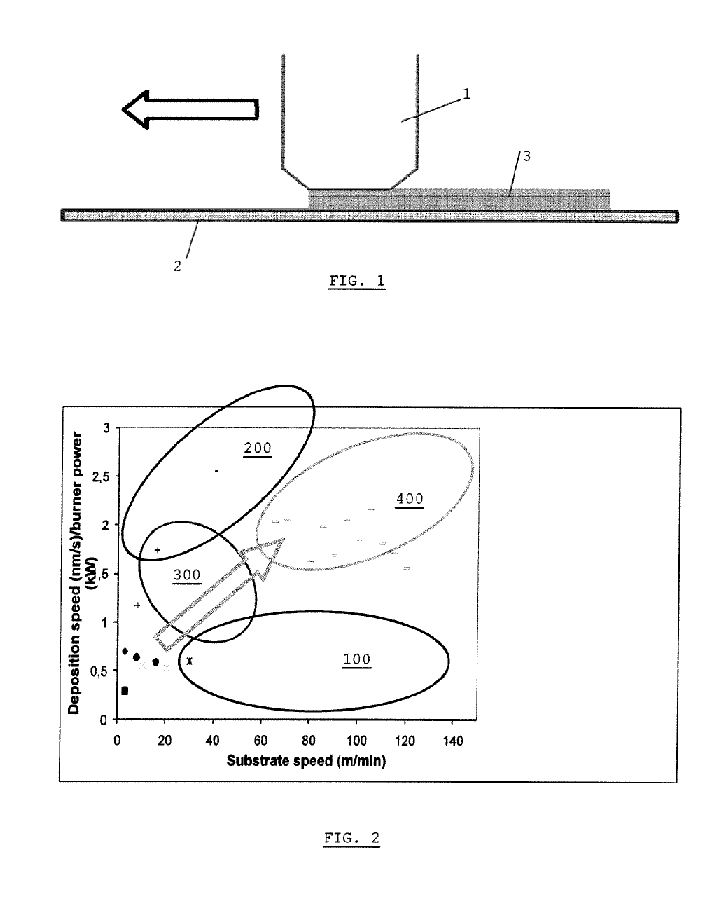

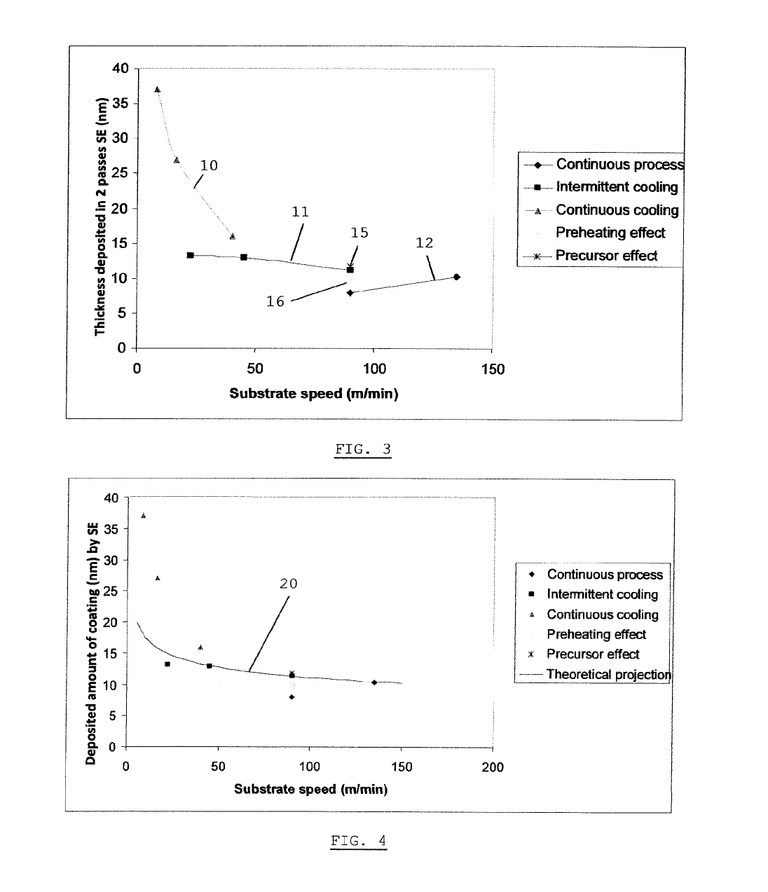

The invention is illustrated for the case of pre-painted steel substrates in the graph in FIG. 2, which shows the net deposition speed achieved per unit of burner power dissipated, as a function of the relative substrate speed during FACVD deposition. Hence the y-axis gives an idea about the flux of activated precursor towards the surface per unit of power dissipated in the process. The x-axis shows the relative speed of the substrate with respect to the flame. The various points correspond to various tested samples. All points in the graph that correspond to relative substrate speeds below 40 m/min were measured with external water cooling. All points above 40 m/min were measured without external cooling.

In the low deposition speed region 100, the amount of material deposited on the surface is limited. This can be caused by various reasons (dynamic temperature in each case is too low):

too low energy flux towards the surface

too low activated precursor flow towards the surface (too little exergy)

too much dissipative processes active, resulting in too high entropy locally, e.g. if there is much turbulence locally in the zone where the activated precursor is present.

In the ‘powder formation’ region 200, the activated precursor forms too much powder. This is nearly always the case if too much precursor is added to the gas mixture. In this case the exergy flow by the activated precursor is very high (a high amount of free enthalpy of the activated precursor is added). The dynamic surface temperature will be too high and in general the coating will have bad adhesion.

In the ‘intermediate property’ region 300, the coating is not very adherent. The coating is rather porous and does not have the same layer properties as at lower substrate speeds. This is achieved by rather high precursor additions at somewhat higher substrate speeds than in the ‘powder formation’ region. The higher substrate speed lowers the energy transmission to the substrate, while the free enthalpy flow of the activated precursor remains rather high (dynamic temperature OK, but much mixing of fluid elements). However, with intermittent cooling (see further), a good coating quality can be obtained in this region, at speeds of higher than 30 m/min and up to about 60 m/min, also leading to a ‘drag effect’.

In order to have a coating with good properties and a high relative substrate speed (region 400—higher than about 60 m/min), the mixing of fluid elements in the gas phase that contains the activated precursor should be minimized. This will lower the fractal surface of the aggregates that form. This means that the entropy production in the gas phase must be lowered. This can be achieved by going to combinations in the process of substrate speeds and gas flows that allow the most optimal form of the ‘drag effect’. This preferred combination will be evidenced by the transition from a reaction speed controlled regime to a diffusion controlled regime, since in the drag effect, the process gases will be forming the boundary layer of the substrate. The actual position of the regions 100-400 may differ for different substrate materials.

Under the conditions symbolized by the region 400, the total entropy flow towards the surface will be lowered, as well as the heat flux towards the surface, so that the dynamic temperature is altered. Enough exergy will need to be supplied to the surface in order to have a dynamic process temperature that is in the required interval. Hence at the higher process speeds according to the invention, the amount of activated precursor in the gas phase must be increased and/or the temperature of the substrate must be increased, with respect to FACVD at lower substrate speeds wherein no external cooling is required. In practice this means that the precursor flow and/or the substrate pre-heating temperature is higher in the method of the invention than in known FACVD methods without external cooling.

It is also to be noted from FIG. 2 that a CVD deposition at high substrate speeds according to the invention is more efficient than the CVD deposition at lower substrate speeds: FIG. 2 shows the deposition speed (in nm thickness of coated layer per s) per unit burner power. So the method of the invention provides a higher coating thickness for the same power delivered by the burner.

In stead of the set-up of FIG. 1, it is also possible to coat the substrate by reversing the setup of FIG. 1, i.e. by supplying the flame and precursor flow upwards towards a substrate moving with respect to the flame above said flame. It is also possible to move the substrate in a vertical plane and supply the flame and precursor horizontally. The method of the invention is thus not limited to the substrate being positioned above the flame. The method of the invention may be applied simultaneously on both sides of a substrate.

According to preferred embodiments, the precursor that is used in the invention is suitable for forming a silicon-oxide coating on the surface. An example thereof is hexamethyldisiloxane (HMDSO).

A number of test results are now presented which illustrate the invention. The tests were performed on pre-painted steel substrates. The paint layer was a polyester based paint. The tests were performed under various conditions:
Continuous cooling: in this case, the substrate is placed on a holder with thermostatic properties regulated by a large water bath. In this case the heat flux that can be generated is high.
Intermediate cooling: the samples are placed on a roll and cooling is done after 2 passes of deposit by moving the roll away from the burner during 4 seconds and by keeping the roll moving. Since air is used as a cooling medium, the heat flux drawn from the substrate is much lower. One pass is defined as a continuous movement of an FACVD head relative to the substrate or vice versa, wherein during the movement no external cooling is done.
Continuous process (no external nor intermittent cooling): the roll is left continuously under the burner during the deposit. The amount of heat withdrawn from the substrate by the carrier is hence further reduced. The same effect is obtained by a burner which moves in subsequent passes relative to a substrate, without interruption between the passes.

FIG. 3 shows the thickness deposited in two passes as a function of the relative substrate speed for a number of test samples (symbols ▴, ♦ and ▪). Curve 10 is valid for continuous cooling, curve 11 for intermittent cooling, and curve 12 for the continuous process (no cooling). All measurement points correspond to ‘good’ coatings in terms of coating thickness and carbon black/colour measurements (delta E<1 for 1 cycle, see annex). The precursor used was HMDSO, added to the FACVD flame at 400 μL/min. The pre-heating temperature of the substrate was 40° C. for all points on the curves. FACVD was performed with a burner that was 22 cm broad, and with an air flow of 200 L/min and a propane flow of 9.1 L/min. The distance substrate/burner was 1 cm.

It was found that with the continuous cooling process (curve 10), no good coatings could be obtained at speeds above 45 m/min. With intermittent cooling (curve 11), speed could be increased to about 90 m/min before coating thickness became too low. With the continuous process, the speed could be further increased to 120 m/min whilst maintaining good coating quality.

These results prove that the higher process speeds result in an increasing ‘cooling effect’, that is beneficial for a good coating formation, to the degree that external cooling becomes less and less necessary, to the point of being not needed. Together with the ‘drag effect’, this results in the formation of high quality coatings on materials which could not so far be coated by FACVD.

The measurement points 15 and 16 represent measurements with the continuous process (no external cooling) at 90 m/min and with higher values for the precursor flow and substrate pre-heating temperature. Sample 15 was coated with 600 μL/min precursor flow and sample 16 with 75° C. pre-heating temperature. It can be seen that in both cases the layer thickness increased. The carbon black/colour measurement was still good. Increasing one of these parameters further deposits “bad coatings”. There is a gain in amount deposited by increasing the precursor or pre-heating temperature, however, the intermittent cooling process with 400 μl/min and 40° C. deposits the coating with greater efficiency.

Reference is furthermore made to FIG. 4, which shows the same test results as in FIG. 3, but wherein the maximum deposited amounts for speeds greater than 40 m/min are plotted in a log/log plot of the amount deposited versus the substrate speed. It can be seen that a slope of −0.2 is obtained (see best fit curve 20 in FIG. 4). This indicates that the deposited amount is proportional to the substrate speed to a power −0.2. This is a similar speed dependency as the thickness of a turbulent boundary layer for flat substrates (see e.g. “Perry's chemical engineers handbook”, R. H. Perry and D. W. Green, pp. 6-40). At substrate speeds lower than 40 m/min, the dependency is different.

The conclusion of these tests is that for pre-painted steel substrates of the type tested, good quality coatings can be obtained in a speed range between 110 and 140 m/min for the above-described continuous process (no external cooling and no intermittent cooling), with a HMDSO flow of 400-600 μL/min and a pre-heating temperature of the substrate of 40-75° C. With intermittent cooling, good coatings can be obtained for substrate speeds higher than 30 m/min and up to around 110 m/min for the same ranges of HMDSO flow and pre-heating temperature.

The precursor flow value must be regarded relative to the burner gas flow of 209.11/min in the tested case (flow of air and propane). The preferred range for the ratio of the precursor flow relative to the burner gas flow is then between 1.9×10⁻⁶ and 2.8×10⁻⁶. Also for other precursor types and substrate types, the above limits represent the preferred range for the precursor flow ratio relative to the burner gas flow (1.9×10⁻⁶−2.8×10⁻⁶), and for the substrate pre-heating temperature (40-75° C.)

Further tests have revealed optimal speed windows for the following substrate materials at a precursor flow ratio relative to the burner gas flow of 1.9×10⁻⁶ (though valid for higher values as well), coated by the above-described continuous process (no external cooling and no intermittent cooling) and with HMDSO as the precursor (though valid for other precursors as well):

Glass: higher than 30 m/min and up to 80 m/min, according to another embodiment between 30 m/min and 50 m/min.
Laminate: between 40 m/min and 100 m/min
Wood: between 40 m/min and 100 m/min
Polystyrene (PS): between 60 m/min and 100 m/min, according to another embodiment between 80 m/min and 100 m/min.
Polymethylmethacrylate (PMMA): between 60 m/min and 110 m/min, according to another embodiment between 80 m/min and 110 m/min.
Polyvinylchloride (PVC): between 90 m/min and 100 m/min
Polypropylene (PP): between 120 m/min and 140 m/min
Textile: between 120 m/min and 140 m/min
Polycarbonate (PC): between 60 m/min and 140 m/min
The method of the invention is applicable to other materials as well. According to a preferred embodiment, said materials do not include silicone rubber.

The method of the invention can be applied in various fields. One example is the use of the method in the production of solar cells, wherein a SiOx layer is applied on the glass layer protecting the polycrystalline Si-layer of the solar cell, for example for giving self-cleaning properties to the glass layer. Instead of a glass layer, a polycarbonate layer may be used, provided with a SiOx layer according to the method of the invention, for providing self-cleaning and anti-reflective properties to the polycarbonate. In particular in the latter application, the method is useful given that PC is a heat sensitive material which cannot be coated by FACVD at speeds below 30 m/min.

According to an embodiment of the method of the invention for depositing a coating on a heat-sensitive substrate, two or more deposition passes are done on the same portion of the substrate, without any external cooling of the substrate during the deposition, after which the substrate is left to cool down to its initial temperature (room temperature or a preheating temperature). Alternatively, the substrate is cooled down to its initial temperature by forced cooling (for example forced air cooling or water cooling) in between the steps. One pass is defined as a continuous movement of an FACVD head relative to the substrate or vice versa. This can be a movable FACVD head moving linearly over a flat substrate, or a substrate mounted onto a rotating cylinder, moving underneath a stationary FACVD head. A sequence of such passes is hereafter called a deposition step. The method comprises two or more deposition steps, with a cooling step (cooling down under ambient or forced cooling) in between deposition steps and after the last deposition step. Each pass is performed at a relative speed between the FACVD head and the substrate of more than 30 m/min, preferably more than 40 m/min, more preferably more than 50 m/min. The maximum speed depends on the type of substrate and coating applied.

Preferred specific process parameters are given hereafter for the cases where the heat sensitive material is Poly Vinyl Chloride (PVC), Acrylonitrile Butadiene Styrene (ABS) or polypropylene (PP).

For PP, the following conditions are preferred:
relative speed between burner and substrate: between 80 m/min and 200 m/min coating in a number of deposition steps of two or three passes in each step, with a cooling time under ambient air of at least 10 min between steps,
pre-heating the substrate before coating to a pre-heating temperature between 40° and 75° C.
   According to a preferred embodiment, the number of steps applied on PP is 3 or 4. According to a further preferred embodiment, the distance substrate-burner is 1 cm.

For PVC, the following conditions are preferred:
relative speed between burner and substrate: between 60 m/min and 80 m/min,
coating in a number of deposition steps of two or three passes in each step, with a cooling time under ambient air of at least 10 min between steps.
no pre-heating
   According to a preferred embodiment, the number of steps applied on PVC is 3 or 4. According to a further preferred embodiment, the distance substrate-burner is 1.5 cm.

For ABS, the following conditions are preferred:
relative speed between burner and substrate: between 60 m/min and 200 m/min, according to another embodiment between 80 m/min and 200 m/min
coating in a number of deposition steps of two or three passes in each step, with a cooling time under ambient air of at least 10 min between steps,
no pre-heating.
   According to a preferred embodiment, the number of steps applied on ABS is 3 or 4. According to a further preferred embodiment, the distance substrate-burner is 1.5 cm.

Apart from the above, the following process parameters are preferred for all three materials:
200-600 μl/min precursor flow,
ratio precursor flow/burner gas flow (fuel gas+air) between 0.9×10⁻⁶ and 2.8×10⁻⁶ (liter_{precursor}/liter_{gas}), note: precursor is liquid phase and gasses gas phase
distance between the burner and the substrate between 10 mm and 15 mm.

For example, the precursor flow can be a HMDSO flow of 400 μl/min, the FACVD burner can be fuelled by a propane flow of 9.1 L/min, and an air flow of 200 l/min (burner gas flow is 209.1 L/min, ratio is 1.9×10⁻⁶).

According to preferred embodiments, the precursor that is used in the invention is suitable for forming a silicon-oxide coating on the surface. A preferred precursor is hexamethyldisiloxane (HMDSO): applied under the above conditions, this precursor allows to produce a coating on all three materials PP, PVC and ABS with good easy-to-clean properties.

While the invention has been illustrated and described in detail in the drawings and foregoing description, such illustration and description are to be considered illustrative or exemplary and not restrictive. Other variations to the disclosed embodiments can be understood and effected by those skilled in the art in practicing the claimed invention, from a study of the drawings, the disclosure and the appended claims. In the claims, the word “comprising” does not exclude other elements or steps, and the indefinite article “a” or “an” does not exclude a plurality. The mere fact that certain measures are recited in mutually different dependent claims does not indicate that a combination of these measures cannot be used to advantage. Any reference signs in the claims should not be construed as limiting the scope.

The foregoing description details certain embodiments of the invention. It will be appreciated, however, that no matter how detailed the foregoing appears in text, the invention may be practiced in many ways, and is therefore not limited to the embodiments disclosed. It should be noted that the use of particular terminology when describing certain features or aspects of the invention should not be taken to imply that the terminology is being re-defined herein to be restricted to include any specific characteristics of the features or aspects of the invention with which that terminology is associated.

### Annex: Description of Carbon Black and Colour Measurements Performed on Pre-Painted Samples

### Preparation C-Black Solution 10%

To 5 g C-black powder (Soot FW200 Degussa) 45 g H2O is added. The suspension is vigorously stirred and remains stable.

### Testing Procedure

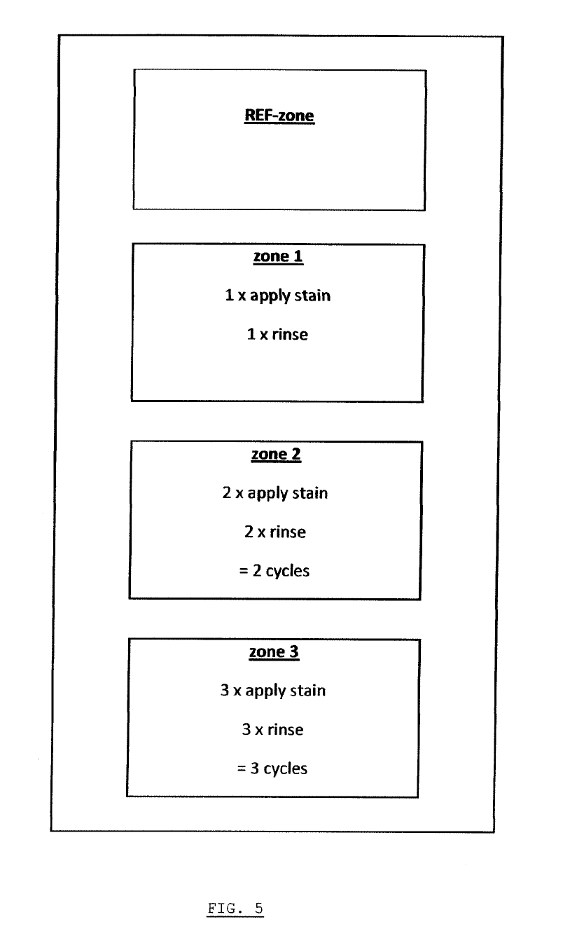

All samples are rinsed with DI water en blow-dried before the test. The samples are conditioned for 24 h at room temperature. The test sample is divided into 4 zones (see FIG. 5).

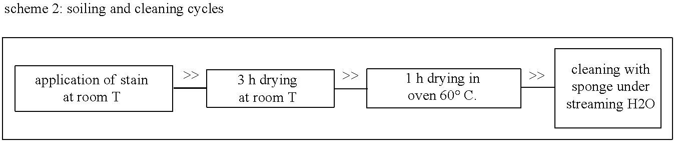

Whenever the test is applied, 3 stains are applied on the first day in zones 1 to 3. With a pipette 5 droplets are applied of the suspension on each zone. The stain is then smeared out using a spatula to a zone approximately 2 cm×3 cm. The cycle of scheme 2 then follows.
At the end of a cycle the stains are wiped away under streaming H20.
The cycle is repeated twice in zone 2 and three times in zone 3. The change in colour is measured by a colour measurement.

### Colour Measurement

Colour measurement is performed using BYK GARDNER SPRECTRO GUIDE SPHERE GLOSS according to HND 250_{—}072. (D65/10).

Colour is presented in a scale with 3 axis that characterise the colour:
L: luminance from 0 (dark) to 100 (bright)
a: green-red-axis −60 (green) to +60 (red)
b: blue-yellow-axis −60 (blue) to +60 (yellow)
   A colour change is defined by a value for ΔE. The value for the latter is calculated as:

ΔE=\sqrt{(L₂−L₁)²+(a₂−a₁)²+(b₂−b₁)²}

This ΔE yields the colour change between surface 2 (L2, a2, b2) and surface 1 (L1, a1, b1).
The following qualitative evaluation is made with the value for ΔE:
If ΔE<1.0 the colour change is not noticeable with the bare eye.
If ΔE>2.4 the colour change is significant.

1. A method for depositing a coating on a substrate, said substrate consisting of or comprising on its surface a material other than silicone rubber, by a flame-assisted chemical vapour deposition technique, wherein the substrate is exposed to a flame produced by a burner, while a flow of precursor elements is added to said flame, and wherein the substrate is subjected to a relative movement with respect to said burner wherein the flame is dragged out along a reaction zone situated behind the burner, and wherein the relative speed of the substrate with respect to the flame is higher than 30 m/min, wherein no external cooling is done on the substrate during said relative movement.

2. Method according to claim 1, wherein the substrate comprises on its surface or consists of a heat sensitive material.

3. (canceled)

4. Method according to claim 1, wherein the substrate comprises on its surface or consists of a polyester based material or an organic material.

5. Method according to claim 1, wherein the substrate is a metal substrate painted with a polyester based paint layer or with an organic film.

6. Method according to claim 4, wherein intermittent cooling is applied and wherein the relative substrate speed is between 40 m/min and 110 m/min

7. Method according to claim 4, wherein no external cooling and no intermittent cooling is applied and wherein the relative substrate speed is between 110 m/min and 140 m/min.

8. Method according to claim 1, wherein the substrate comprises on its surface or consists of glass, wherein no external cooling and no intermittent cooling is applied and wherein the relative substrate speed is higher than 30 m/min and up to 80 m/min.

9. Method according to claim 1, wherein the substrate comprises on its surface or consists of polystyrene, wherein no external cooling and no intermittent cooling is applied and wherein the relative substrate speed is between 60 m/min and 100 m/min.

10. Method according to claim 1, wherein the substrate comprises on its surface or consists of polymethylmethacrylate, wherein no external cooling and no intermittent cooling is applied and wherein the relative substrate speed is between 60 m/min and 110 m/min.

11. Method according to claim 1, wherein the substrate comprises on its surface or consists of polypropylene or textile, wherein no external cooling and no intermittent cooling is applied and wherein the relative substrate speed is between 120 m/min and 140 m/min.

12. Method according to claim 1, wherein the substrate comprises on its surface or consists of polycarbonate, wherein no external cooling and no intermittent cooling is applied and wherein the relative substrate speed is between 60 m/min and 140 m/min.

13. Method according to claim 1, wherein the substrate comprises on its surface or consists of laminate or wood, and wherein no external cooling and no intermittent cooling is applied and wherein the relative substrate speed is between 40 m/min and 100 m/min.

14. Method according to claim 1, wherein the substrate comprises on its surface or consists of polyvinylchloride, and wherein no external cooling and no intermittent cooling is applied and wherein the relative substrate speed is between 90 m/min and 100 m/min.

15. Method according to claim 1, wherein the ratio of the precursor flow relative to the burner gas flow is between 1.9×10⁻⁶ and 2.8×10⁻⁶ and/or wherein the substrate pre-heating temperature is between 40° C. and 75° C.

16. Method according to claim 1, wherein the precursor elements are configured to produce a silicon oxide coating.

17. Use of the method according to claim 8 in the production of solar cells comprising a glass or polycarbonate layer, wherein a layer of silicon oxide is applied onto said glass or polycarbonate layer.

18. A method according to claim 1, wherein the substrate comprises on its surface or consists of a heat sensitive material, wherein the coating deposition takes place in two or more deposition steps on a optionally pre-heated substrate, each deposition step consisting of a number of subsequent passes on the same portion of the substrate, each pass consisting of a movement of the substrate relative to the flame at a speed of more than 30 m/min and wherein after each deposition step, the substrate is subjected to a cooling step, wherein the substrate cools down to its initial temperature.

19. Method according to claim 18, wherein the substrate is removed from the flame after each step, during a period sufficiently long to let the substrate cool down under ambient air to its initial temperature.

20. Method according to claim 18 wherein the substrate is removed from the flame after each step and cooled down to its initial temperature by forced cooling.

21. Method according to claim 18, wherein said heat sensitive material is polypropylene (PP), polyvinylchloride (PVC) or Acrylonitrile Butadiene Styrene (ABS).

22. Method according to claim 21, wherein said heat-sensitive material is PP, and wherein
the relative speed between the flame and the substrate is between 80 m/min and 200 m/min,
each step comprises two or three passes,
the cooling time between steps is at least 2 minutes,
the substrate is preheated to a temperature between 40° C. and 75° C.

23. Method according to claim 21, wherein said heat-sensitive material is PVC, and wherein:
the relative speed between the flame and the substrate is between 60 m/min and 80 m/min,
each step comprises two or three passes,
the cooling time between steps is at least 10 minutes,
the substrate is not pre-heated.

24. Method according to claim 21, wherein said heat-sensitive material is ABS, and wherein:
the relative speed between the flame and the substrate is between 80 m/min and 200 m/min,
each step comprises two or three passes,
the cooling time between steps is at least 10 minutes,
the substrate is not pre-heated.

25. Method according to claim 18, wherein
the precursor flow is between 200 μl/min and 600 μl/min,
the ratio of the precursor flow relative to the burner gas flow (fuel gas+air) is between 0.9×10⁻⁶ and 2.8×10⁻⁶ (liter_{precursor}/liter_{gas}),
the distance burner substrate is between 10 mm and 15 mm.

26. Method according to claim 18, wherein the number of steps is 3 or 4.
